(19) United States
(12) Patent Application Publication
(10) Pub. No.: US 2015/0048727 A1
(43) Pub. Date: Feb. 19, 2015

(54) MOUNTING APPARATUS FOR EXPANSION CARD AND MOUNTING ASSEMBLY

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: ZHEN-HUA LIU, Wuhan (CN); XIAO-WEN DUAN, Wuhan (CN); DA-LONG SUN, Wuhan (CN)

(21) Appl. No.: 14/460,763

(22) Filed: Aug. 15, 2014

(30) Foreign Application Priority Data
Aug. 16, 2013 (CN) 2013103574342

(51) Int. Cl. H05K 7/14

(52) U.S. Cl. CPC H05K 7/1409
USPC 312/223.2; 403/322.4

(57) ABSTRACT

A single mounting apparatus for securing a number of expansion cards includes a resisting member rotatably attached to the chassis and a clamping buckle. The clamping buckle includes a pressing piece, a supporting portion, an operating portion, and a catching member. A securing space is defined in the resisting member for latching the catching member. When the catching member is caught in the securing space, the securing member is clamped between a flange of the chassis and the resisting member to stop the rotation of the resisting member. The pressing piece presses down on and secures the expansion cards. Lifting the clamping buckle upwards unlatches the catching member from the securing space and causes re-rotation of the resisting member to allow dismounting of the expansion cards.

### FIELD

The present disclosure relates to a mounting apparatus for expansion cards and a mounting assembly.

### BACKGROUND

Sound cards and network cards are widely used in various electronic devices as expansion cards. The expansion cards are inserted into PCI (Peripheral Component Interconnect) slots of the electronic devices by way of mounting apparatuses.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus for a plurality of expansion cards.

FIG. 2 is similar to FIG. 1, but viewed from another aspect.

FIG. 3 is a side view of a securing member of the mounting apparatus of FIG. 1.

FIG. 4 is another view of the securing member of FIG. 1.

FIG. 5 is an enlarged view of a resisting member of the mounting apparatus of FIG. 2.

FIG. 6 is an assembled view of the mounting apparatus of FIG. 1.

FIG. 7 is a cross-sectional view of the mounting apparatus taken along line VIII-VIII of FIG. 6, showing the securing member in a non-securing state.

FIG. 8 is another cross-sectional view of the mounting apparatus taken along line VIII-VIII of FIG. 6, showing the securing member in a securing state.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

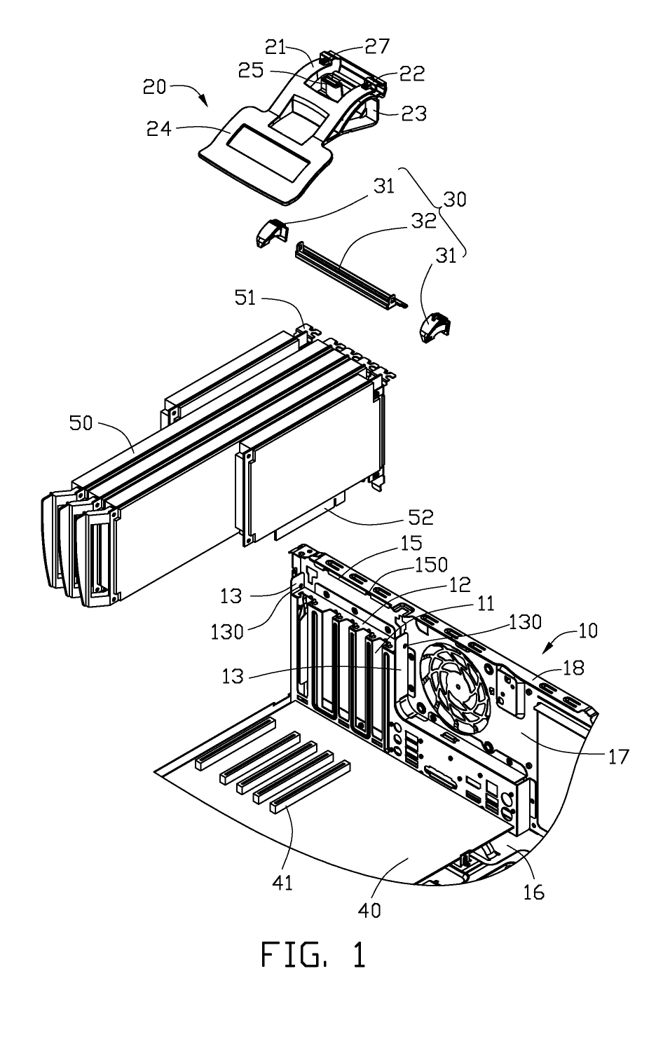

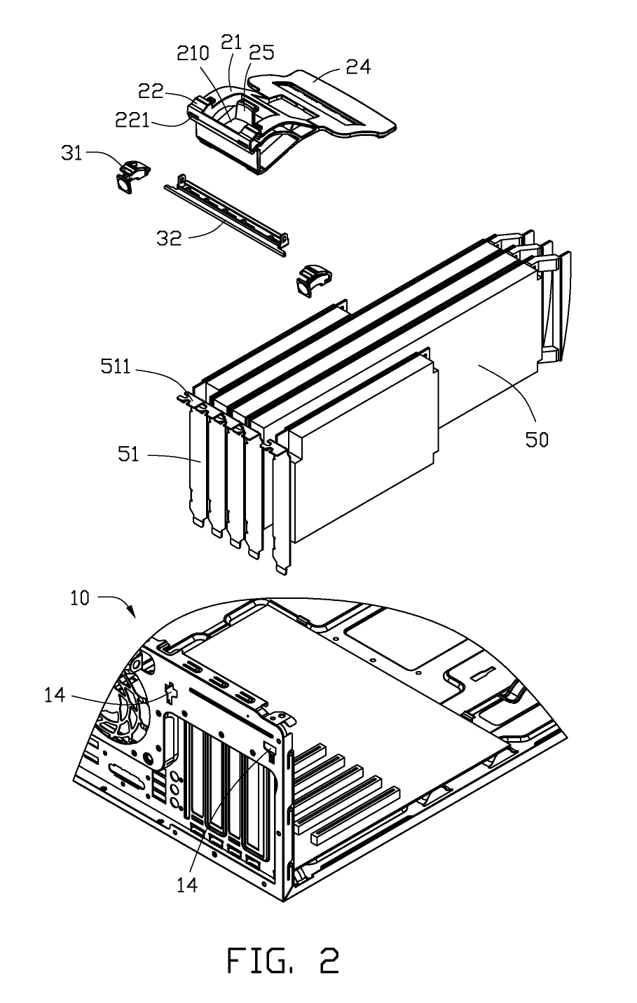

FIGS. 1 and 2 illustrate an embodiment of a mounting apparatus for securing a plurality of expansion cards 50 to a circuit board 40 of an electronic device. In at least one embodiment, the electronic device is a computer.

The circuit board 40 is located in a chassis 10 of the electronic device. A plurality of PCI slots 41 is mounted on the circuit board 40 for connecting the plurality of expansion cards 50. Each of the expansion cards 50 includes an inserting portion 52 for inserting into a PCI slot 41. A stopping piece 51 can be connected to a vertical edge of each expansion card 50. The stopping piece 51 is substantially L-shaped, and comprises a main piece and a stopping tab 511 extending substantially perpendicularly from a top edge of the main piece.

The chassis 10 comprises a bottom plate 16 and a rear plate 17 which connects to the bottom plate 16 perpendicularly. The circuit board 40 is located on the bottom plate 16. A plurality of evenly-spaced expansion slots 11 is defined in the rear plate 17. The rear plate 17 includes a supporting piece 12 connected to a top of each expansion slot 11 and substantially parallel to the bottom plate 16. A pair of pivot mounting pieces 13 extends substantially perpendicularly from opposite ends of the supporting piece 12. A pivot hole 130 is defined in each of the pair of pivot mounting pieces 13. A pair of accommodating slots 14 is defined in the rear plate 17. Each of the pair of accommodating slots 14 is located above the supporting piece 12. A first flange 18 extends substantially perpendicularly from a top edge of the rear plate 17. A second flange 15 extends downward and perpendicularly from the first flange 18. The second flange 15 is parallel to the rear plate 17.

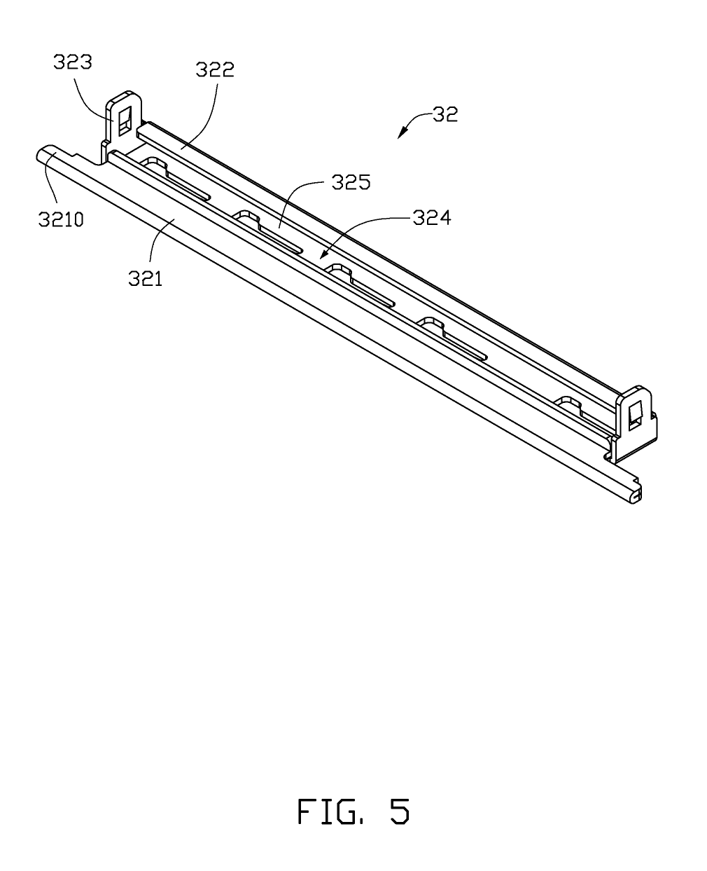

Referring to the FIGS. 1 and 5, the mounting apparatus includes a resisting member 30 pivotally mounted in the chassis 10. The resisting member 30 comprises a pair of mounting members 31 and a resisting piece 32. The resisting piece 32 includes a base piece 325 and a pair of securing pieces 323 extending vertically from opposite ends of the base piece 325. The resisting piece 32 includes a latching piece 322 that is located between the pair of securing pieces 323 and substantially parallel to the base piece 325. A rotating piece 321 extends horizontally from the base piece 325. A pivot tab 3210 is located at each of the two ends of the rotating piece 321.

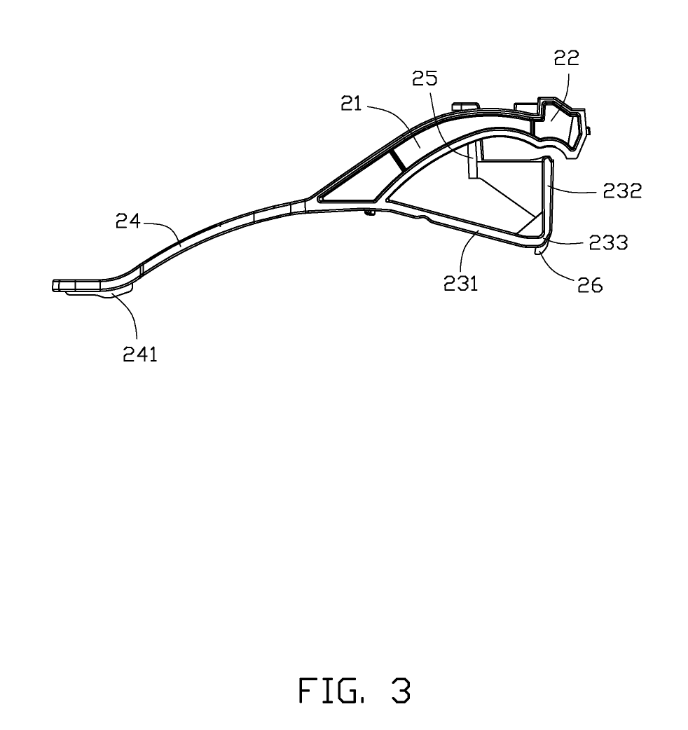

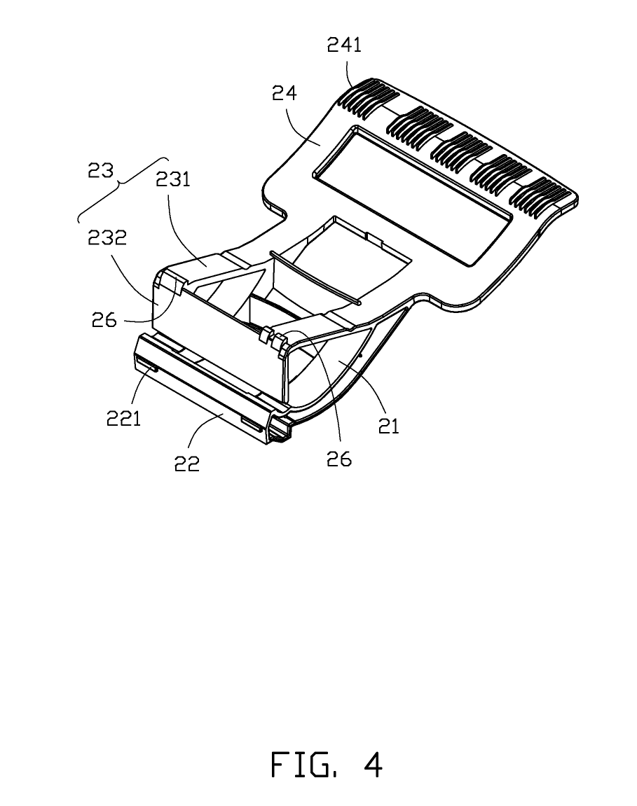

Referring to FIGS. 1 to 4, the mounting apparatus further includes a securing member 20 for securing the plurality of expansion cards 50. The securing member 20 includes an arcuate mounting piece 21. A through hole 210 is defined in the arcuate mounting piece 21. A mounting portion 22 extends from a rear side of the arcuate mounting piece 21, and top of the mounting portion 22 protrudes from the mounting piece 21. A pair of protrusions 221 protrudes from a rear side of the mounting portion 22. A pair of positioning portions 27 protrudes from the mounting piece 21 and abuts the top of the mounting portion 22. A pair of cutouts 150 is defined in the second flange 15 corresponding to the pair of positioning portions 27.

A supporting portion 23 extends from the mounting piece 21. The supporting portion 23 includes a first portion 231 which is connected to the mounting piece 21, and a second portion 232 which extends upward from the first portion 231. An acute angle is formed between the first portion 231 and second portion 232. An angle of the arcuate mounting piece 21 is less than 90 degrees. A joint 233 is formed between the first portion 231 and second portion 232. A plurality of catching members 26 extends downward from the joint 233, and the joint 233 and the plurality of catching members 26 are substantially aligned to the downside of mounting portion 22. A securing space 324 between the base piece 325 and the latching piece 322 is configured to latch the plurality of catching members 26. In one embodiment, each of the plurality of catching members 26 is a hook.

An operating portion 25 extends from the second portion 232. The operating portion 25 is exposed out of the through hole 210 and extended from the through hole 210. An arcuate pressing piece 24 is connected to a joint between the mounting piece 21 and first portion 231. The degree of curvature of the pressing piece 24 is not the same as the degree of curvature of the mounting piece 21. A plurality of spaced positioning teeth 241 is located at a downside of the pressing piece 24. The plurality of positioning teeth 241 and the mounting portion 22 are located at opposite ends of the securing member 20. A distance between two adjacent positioning teeth 241 is substantially equal to a thickness of each expansion card 50.

In one embodiment, the securing member 20 is integrally formed and is a resilient member.

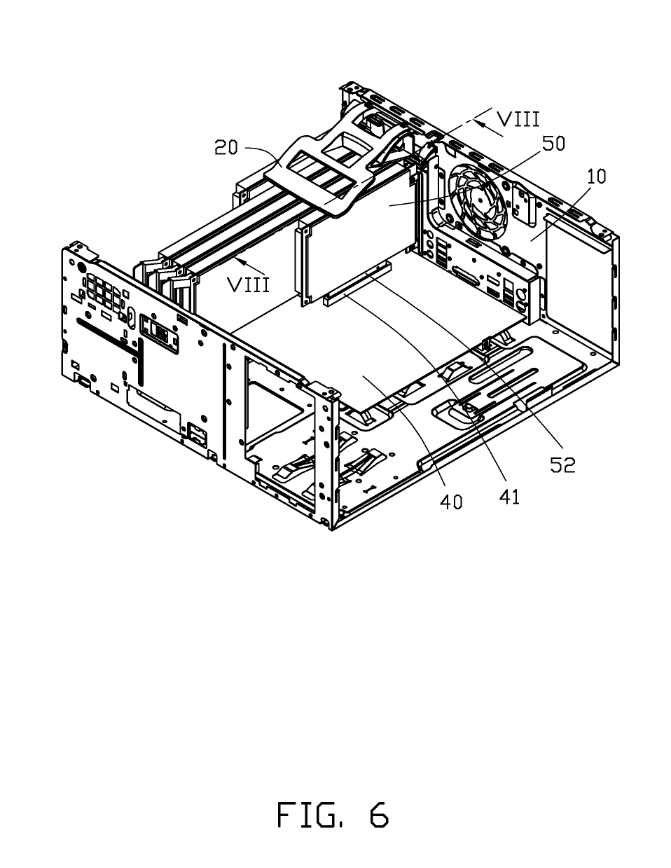

FIGS. 6 to 8 illustrate assembly of mounting apparatus for securing the plurality of expansion cards 50 to the circuit board 40, in which the pair of mounting members 31 is securing to the pair of securing pieces 323 by fastening, riveting, or any other means. The pair of pivot tabs 3210 extends into the pivot holes 130 to rotatably mount the resisting member 30 in the chassis 10. The pair of mounting members 31 extends into the pair of accommodating slots 14. The resisting piece 32 can be rotated between a first position and a second position about the pair of pivot tabs 3210.

When the resisting piece 32 is rotated to the second position along a first direction, the resisting piece 32 is distanced from the supporting piece 12. The plurality of expansion cards 50 can be mounted to the circuit board 40, and when the plurality of inserting portions 52 is inserted in the PCI slots 41, the stopping piece 51 of each expansion card 50 is received in an expansion slot 11 with the stopping tab 511 abutting the supporting piece 12. When the resisting piece 32 is rotated to the first position along a second direction which is opposite to the first direction, the resisting piece 32 abuts the supporting piece 12. The stopping tab 511 resists between the resisting piece 32 and supporting piece 12, thereby securing the stopping tab 511 on the supporting piece 12.

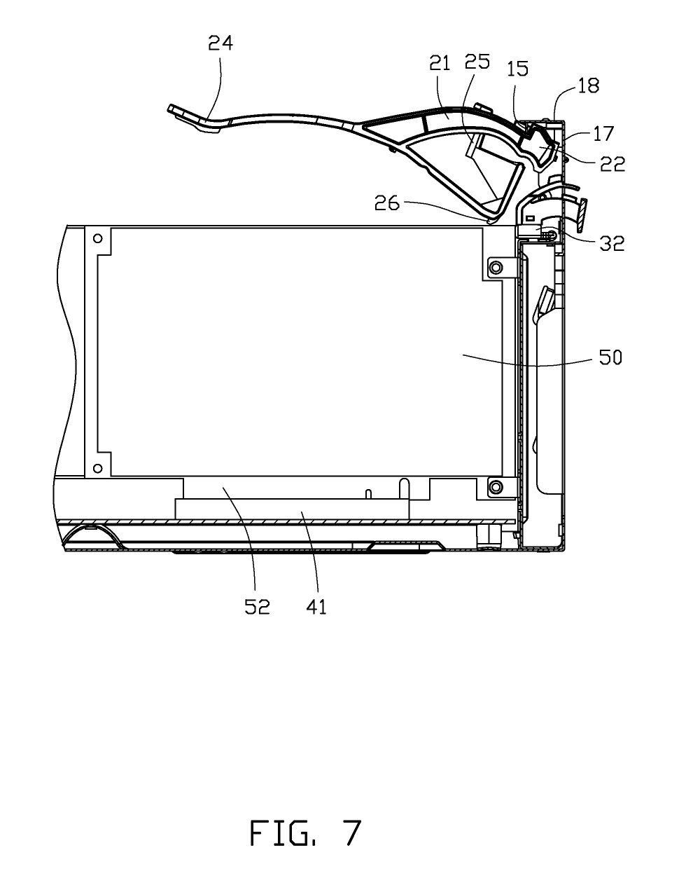

The securing member 20 is located above the plurality of expansion cards 50 in a non-securing state (see FIG. 7). The top of the mounting portion 22 is latched by the second flange 15. The pair of positioning portions 27 is aligned to the pair of cutouts 150.

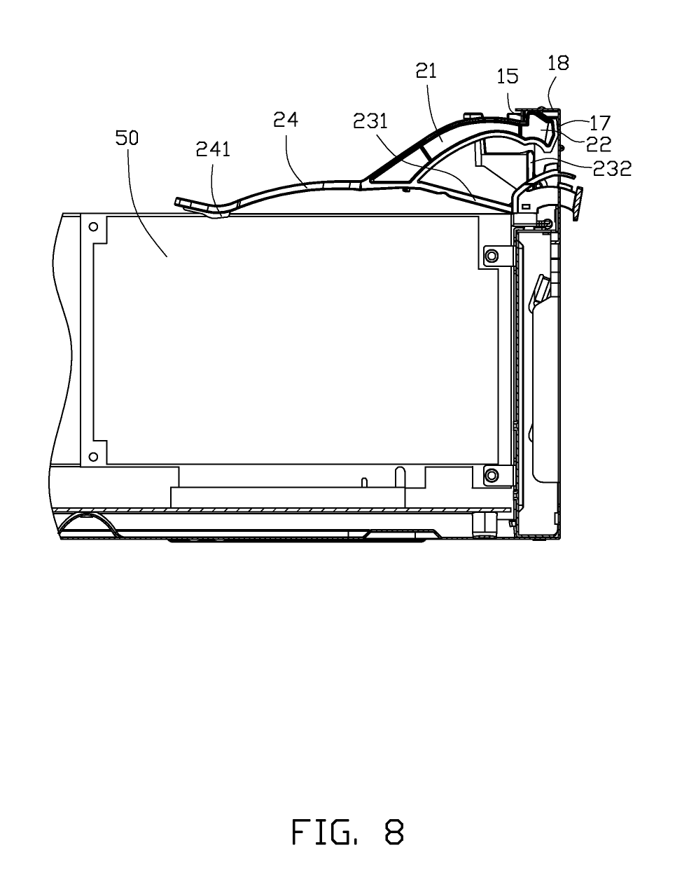

When the mounting piece 21 is pressed down, the securing member 20 is deformed (see FIG. 8). The plurality of catching portions 26 are caught in the securing space 324. The top of the mounting portion 22 is latched between the rear plate 17 and second flange 15, and the pair of protrusions 221 abuts the rear plate 17. At the same time, the mounting portion 22 is clamped between the first flange 18 and the base piece 325. Each of the expansion cards 50 is gripped between two adjacent positioning teeth 241. The pressing piece 24 presses and further secures the plurality of expansion cards 50 onto the chassis 10.

In disassembly, the operating portion 25 is moved, the second portion 232 moves relative to the first portion 231 together with the operation portion 25. The joint 233 is deformed by the movement of the second portion 232. The catching portion 26 is detached from the securing space 324. The mounting portion 22 is detached from the space between the second flange 15 and rear plate 17, because of the decompression of the securing member 20. The pressing piece 24 moves away from the plurality of expansion cards 50. The securing member 20 moves away from the chassis 10 and rotates the resisting member 30 to the second position. The resisting piece 32 releases the stopping tab 511 of each expansion card 50 and allows dismounting of the plurality of expansion cards 50 from the chassis 10.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus for an expansion card (50) with a stopping piece (51), comprising:
a chassis (10) with a first flange (18);
a securing member (20) attached to the chassis (10), and comprising a pressing piece (24) and a catching member (26); and
a resisting member (30), rotatably attached to the chassis (10) for resisting the stopping piece (51), and defining a securing space (324) configured to latch the catching member (26);
wherein when the catching member (26) is caught into the securing space (324), the securing member (20) is clamped between the first flange (18) and the resisting member (20) thereby preventing the rotation of the resisting member (20), and the pressing piece (24) presses and secures the expansion card (50); and
wherein when the catching member (26) is unlatched from the securing space (324), the securing member (20) is rendered detachable from the chassis (10) for releasing the expansion card (50).

2. The mounting apparatus of claim 1, wherein the securing member (20) further comprises a supporting portion (23) and an operating portion (25) extending from the supporting portion (23), the catching member (26) extends from the supporting portion (23).

3. The mounting apparatus of claim 2, wherein the supporting portion (23) comprises a first portion (231) and a second portion (232), the first portion (231) and second portion (232) connects to each other; the catching member (26) extends from the bottom of a joint (233) between the first portion (231) and second portion (232).

4. The mounting apparatus of claim 3, wherein the operating portion (25) connects to the second portion (232); the second portion (232) can be move together with the operating portion (25) relative to the first portion (231), the catching member (26) is driven to move with the second portion (232).

5. The mounting apparatus of claim 2, wherein a rear plate (17) and a second flange (15) connect to the opposite edges of the first flange (18) perpendicularly; the securing member (20) further comprises a mounting portion (22), when the catching member (26) is caught in the securing space (324), a top of the mounting portion (22) is latched between the rear plate (17) and second flange (15).

6. The mounting apparatus of claim 5, wherein the catching member (26) is aligned to the mounting portion (22); when the catching member (22) is caught in the securing space (324), the mounting portion (22) and the catching member (26) are clamped between the resisting member (30) and first flange (18).

7. The mounting apparatus of claim 3, wherein a mounting piece (21) extends from the joint between the pressing piece (24) and first portion (231); a through hole (210) is defined in the mounting piece (21) for exposing the operating portion (25).

8. The mounting apparatus of claim 7, wherein the mounting piece (21) is arcuate.

9. The mounting apparatus of claim 8, wherein the pressing piece (21) is arcuate; the degree of curvature of the pressing piece (24) is not the same as the degree of curvature of the mounting piece (21).

10. The mounting apparatus of claim 1, wherein a plurality of positioning teeth (241) extrudes from the pressing piece (24) and evenly-spaced.

11. A mounting assembly, comprising:
an expansion card (50);
a chassis (10) with a first flange (18);
a securing member (20) attached to the chassis (10), and comprising a pressing piece (24), a operating portion (25), a supporting portion (23), and a catching member (26), the supporting portion (23) connecting to and moving together with the operating portion (25); the catching member (26) extending from the supporting portion (23) and moving together with the supporting portion (23); and
a resisting member (30), rotatably attached to the chassis (10) for resisting the expansion card (50), and defining a securing space (324) configured to latch the catching member (26);
wherein when the catching member (26) is caught into the securing space (324), the securing member (30) is clamped between the first flange (18) and the resisting member (30) for stopping the rotation of the resisting member (30), the pressing piece (24) presses and secures the expansion card (50); when the catching member (26) is unlatched from the securing space (324) with the movement of the operating portion (25) and supporting portion (23), the securing member (20) is detachable from the chassis (10) for releasing the expansion card (50).

12. The mounting assembly of claim 11, wherein the supporting portion (23) comprises a first portion (231) and a second portion (232), the first portion (231) and second portion (232) connects to each other; the catching member (26) extends from the bottom of a joint between the first portion (231) and second portion (232).

13. The mounting assembly of claim 12, wherein the operating portion (25) connects to the second portion (232); the second portion (232) can be move together with the operating portion (25) relative to the first portion (231), the catching member (26) is driven to move with the second portion (232).

14. The mounting assembly of claim 11, wherein a rear plate (17) and a second flange (15) connect to the opposite edges of the first flange (18) perpendicularly; the securing member (20) further comprises a mounting portion (22), when the catching member (26) is caught in the securing space (324), a top of the mounting portion (22) is latched between the rear plate (17) and second flange (15).

15. The mounting assembly of claim 14, wherein the catching member (26) is aligned to the mounting portion (22); when the catching member (26) is caught in the securing space (324), the mounting portion (22) and the catching member (26) are clamped between the resisting member (30) and first flange (18).

16. The mounting assembly of claim 12, wherein a mounting piece (21) extends from the joint between the pressing piece (24) and first portion (231); a through hole (210) is defined in the mounting piece (21) for exposing the operating portion (25).

17. The mounting assembly of claim 16, wherein the mounting piece and the pressing piece are arcuate, the radian of the pressing piece is unequal to the radian of the mounting piece.

18. The mounting assembly of claim 17, wherein an angle of the arcuate mounting piece (21) is less than 90 degrees.

19. The mounting assembly of claim 11, wherein a plurality of positioning teeth (241) extrudes from the pressing piece (24), and a distance between two adjacent positioning teeth is substantially equal to a thickness of the expansion card (50).

20. The mounting assembly of claim 11, wherein the securing member (20) is integrally formed and a resilient member.
